(19) United States
(12) Patent Application Publication
(10) Pub. No.: US 2017/0309794 A1
(43) Pub. Date: Oct. 26, 2017

(54) OPTOELECTRONIC SEMICONDUCTOR CHIP AND METHOD FOR PRODUCING AN OPTOELECTRONIC SEMICONDUCTOR CHIP

(71) Applicant: OSRAM Opto Semiconductors GmbH, Regensburg (DE)

(72) Inventor: Norwin VON MALM, Nittendorf (DE)

(73) Assignee: OSRAM Opto Semiconductors GmbH, Regensburg (DE)

(21) Appl. No.: 15/507,747

(22) PCT Filed: Aug. 13, 2015
(86) PCT No.: PCT/EP2015/068674

§ 371 Date: Feb. 28, 2017

(30) Foreign Application Priority Data
Sep. 1, 2014 (DE) 10 2014 112 551.7

(51) Int. Cl. H01L 33/50; H01L 33/60; H01L 33/48; H01L 33/62; C09K 11/06

(52) U.S. Cl. CPC H01L 33/504; H01L 33/62; C09K 11/06; H01L 33/486; H01L 33/60

(57) ABSTRACT

In at least one embodiment, the optoelectronic semiconductor chip (100) comprises a semiconductor layer sequence (1) comprising a top side (2), a bottom side (3) diametrically opposite the top side (2), and an active layer (11) for generating electromagnetic radiation at a first wavelength (10), wherein the semiconductor chip (100) is free of a growth substrate for the semiconductor chip layer sequence (1). The semiconductor chip (100) further comprises a plurality of contact elements (30) which are arranged on the bottom side (3) and can be electronically controlled individually and independently from each other. The semiconductor layer sequence (1) is thereby divided into a plurality of emission regions (20) which are arranged laterally adjacent to one another and are constructed for the purpose of emitting radiation during operation. One of the contact elements (30) is thereby assigned to each emission region (20). Each emission region (20) further comprises a recess in the semiconductor layer sequence (1) which extends from the top side (2) in the direction of the active layer (11). In a top view of the top side (2), the recess of each emission region (20) is completely surrounded by a continuous path made of separating walls (21), wherein the separating walls (21) are formed from the semiconductor layer sequence (1).

An optoelectronic semiconductor chip is provided, together with a method for producing an optoelectronic semiconductor chip.

One object to be achieved is that of providing a semiconductor chip with a plurality of radiation-emitting emission regions, which supplies a high contrast ratio between adjacent emission regions when in operation. A further object to be achieved consists in providing a simple and inexpensive method for producing such a semiconductor chip.

These objects are achieved by the features of the independent claims. Advantageous configurations and further developments constitute the subject matter of the dependent claims.

According to at least one embodiment, the optoelectronic semiconductor chip comprises a semiconductor layer sequence with a top, a bottom opposite the top and an active layer for generating electromagnetic radiation of a first wavelength. The semiconductor layer sequence is preferably in one piece and contiguous.

The top of the semiconductor layer sequence is in particular part of the semiconductor layer sequence and is formed by a semiconductor layer belonging to the semiconductor layer sequence. The top may for example be formed by a plane extending parallel to the active layer or perpendicular to the growth direction of the semiconductor layer sequence, which plane comprises the points of the semiconductor layer sequence furthest away from the active layer. The bottom may also be likewise defined, but the bottom is formed on the other side of the active layer.

The semiconductor layer sequence is preferably based on a III/V compound semiconductor material. The semiconductor material is for example a nitride compound semiconductor material such as AlₙIn₁₋ₙ₋ₘGaₘN or a phosphide compound semiconductor material such as AlₙIn₁₋ₙ₋ₘGaₘP or also an arsenide compound semiconductor material such as AlₙIn₁₋ₙ₋ₘGaₘAs, wherein in each case 0≦n≦1, 0≦m≦1 and m+n≦1 applies. The semiconductor layer sequence may comprise dopants and additional constituents. For simplicity's sake, however, only the essential constituents of the crystal lattice of the semiconductor layer sequence are indicated, i.e. Al, As, Ga, In, N or P, even if these may in part be replaced and/or supplemented by small quantities of further substances. The semiconductor layer sequence is preferably based on AlInGaN.

The active layer of the semiconductor layer sequence in particular contains at least one pn junction and/or at least one quantum well structure. Radiation generated by the active layer when in operation lies in particular in the region of the spectrum between 400 nm and 800 nm inclusive.

According to at least one embodiment, the semiconductor chip is free of a growth substrate for the semiconductor layer sequence. This means that, after growth of the semiconductor layer sequence on a growth substrate, the growth substrate was partially or completely removed. In particular, the semiconductor chip described here is thus a thin-film semiconductor chip, which is mechanically stabilized by a carrier applied to the semiconductor layer sequence after growth.

According to at least one embodiment, the semiconductor chip comprises a plurality of contact elements arranged on the bottom. The contact elements serve to inject current or charge carriers into the semiconductor layer sequence. The contact elements may for example comprise or consist of one or more metals such as Au, Ag, Ni, Al, Cu, Pd, Ti, Rh or a transparent conductive oxide, TCO for short, such as indium-tin oxide, ITO for short. The contact elements are preferably reflective for the light generated by the semiconductor layer sequence.

The contact elements may for example have a rectangular or round or hexagonal or triangular basic shape when viewed in plan view onto the bottom. In particular, the contact elements may be arranged on the bottom in a matrix, i.e. in a regular pattern. It is alternatively also possible for the contact elements to be arranged on the bottom as a plurality of parallel-extending strips.

According to at least one embodiment, the contact elements on the bottom are individually and mutually independently electrically activatable when operated as intended.

That is to say, for example, that each contact element is configured to inject current into the semiconductor layer sequence independently of the other contact elements.

According to at least one embodiment, the semiconductor layer sequence is subdivided into a plurality of emission regions arranged next to one another in the lateral direction, i.e. in a direction parallel to the main plane of extension of the active layer. The individual emission regions may for example individually and/or mutually independently emit electromagnetic radiation of the first wavelength when operated as intended. Each emission region therefore preferably comprises a part of the active layer. Electromagnetic radiation generated in one emission region is preferably outcoupled from the semiconductor layer sequence at the top.

In plan view onto the top, the emission regions are for example arranged adjacent one another. To an observer, the emission regions then appear for example as individual picture elements or pixels, in particular the semiconductor chip constitutes a pixelated display.

According to at least one embodiment, one or more contact elements are associated with each emission region. Through this association, it is for example possible for each emission region to be energized and emit radiation individually and independently of the other emission regions.

According to at least one embodiment, each emission region comprises one, in particular precisely one, recess in the semiconductor layer sequence. The recess extends in this case from the top in the direction of the active layer, but preferably does not penetrate the active layer. That is to say, the semiconductor layer sequence may generate radiation in the region of the recess when operated as intended. The active layer is then preferably a contiguous layer over the entire semiconductor layer sequence, without interruptions and extending over a plurality of emission regions.

According to at least one embodiment, the recess of each emission region is completely surrounded, when viewed in plan view onto the top, by a contiguous web of partitions. The partitions are preferably formed of the semiconductor layer sequence and for example form boundaries or boundary regions between adjacent emission regions.

For example, the partitions extend as far as the top of the semiconductor layer sequence. The partitions surrounding a recess may for example be of a constant height throughout. In particular, the partitions are provided to separate adjacent emission regions from one another optically. To this end, in the region of the partition preferably no or only very little radiation is generated and/or emitted, for example at most 1% or at most 0.1% or at most 0.01% of the radiation which is emitted from the emission regions. The electromagnetic radiation is therefore mainly outcoupled from the semiconductor layer sequence in the region of the recesses.

The recesses in the semiconductor layer sequence, in sectional representation through the semiconductor layer sequence, have the shape for example of a rectangle or of an upside-down truncated cone or of a segment of a circle. In particular, the recess does not itself completely surround a region of the semiconductor layer sequence which extends as far as the top. The recesses are thus preferably not configured as trenches in the semiconductor layer sequence.

In at least one embodiment, the optoelectronic semiconductor chip comprises a semiconductor layer sequence with a top, a bottom opposite the top and an active layer for generating electromagnetic radiation of a first wavelength, wherein the semiconductor chip is free of a growth substrate for the semiconductor layer sequence. The semiconductor chip further comprises a plurality of contact elements arranged on the bottom, which are individually and mutually independently electrically activatable. The semiconductor layer sequence is subdivided into a plurality of emission regions arranged adjacent one another in the lateral direction and configured to emit radiation when in operation. One of the contact elements is associated with each emission region. Each emission region further comprises a recess in the semiconductor layer sequence, which extends from the top in the direction of the active layer. In plan view onto the top, the recess of each emission region is completely surrounded by a contiguous web of partitions, wherein the partitions are formed from the semiconductor layer sequence and wherein the partitions form boundaries between adjacent emission regions.

The semiconductor chip described here is based in particular on the concept of providing a semiconductor chip which may be used as a pixelated display. The controlled introduction of recesses or wells into the semiconductor layer sequence makes it possible to define individual emission regions. Between the recesses, partitions are left which lead, in operation, for example to an improved contrast ratio between adjacent emission regions or pixels. The partitions may in particular prevent crosstalk of the electromagnetic radiation generated in two adjacent emission regions. Furthermore, the recesses may be wholly or partly filled with converter materials and/or scattering materials, such that emission regions are present on a single semiconductor chip with continuous active layer which emit radiation of different wavelengths. In this way it is possible, for example, to produce a television, tablet or cell phone display or a projection device. As a result of the presence of individually, independently activatable contact elements on the bottom of the semiconductor layer sequence, it is moreover possible to supply the various emission regions individually and mutually independently with current and/or activate them individually and mutually independently.

According to at least one embodiment, the recess of at least one emission region is filled at least in part with a converter material. The converter material for example converts the radiation of the first wavelength generated when the relevant emission region is in operation wholly or partly into radiation of a second wavelength different from the first wavelength. A filling level of the converter material in the recesses amounts for example to at least 50% or at least 70% or at least 90% of the height of the partitions. A surface of the converter material remote from the active layer may then be of flat or curved, for example lenticular, configuration.

The converter material for example comprises or consists of an emitter material. In particular, the emitter material may have been introduced into a transparent matrix material.

Possible emitter materials are for example organic molecules and/or luminescent polymers and/or quantum dots. The emitter material for example comprises at least one of the following constituents: polyphenylenvinylene (PPV), acridine dyes, acridinone dyes, anthraquinone dyes, anthracene dyes, cyanine dyes, dansyl dyes, squaryllium dyes, spiropyrans, boron-dipyrromethenes (BODIPY), perylenes, pyrenes, naphthalenes, flavins, pyrroles, porphyrins and the metal complexes thereof, diarylmethane dyes, triarylmethane dyes, nitro dyes, nitroso dyes, phthalocyanine dyes, metal complexes of phthalocyanine, quinones, azo dyes, indophenol dyes, oxazines, oxazones, thiazines, thiazoles, fluorenes, fluorones, pyronines, rhodamines and coumarins. With regard to this and further possible emitter materials, reference is made to document DE 10 2014 105 142 A1, the disclosure content of which is explicitly included by reference.

In particular, the emitter material comprises nano-scale particles with average diameters Q₀ of ≦500 nm or ≦200 nm or ≦100 nm. Alternatively or in addition, the average diameters of the particles may also be ≧1 nm or ≧5 nm or ≧50 nm.

The quantum dots may for example be giant shell quantum dots. These have a core and a shell around the core, wherein the core and the shell comprise or consist of different materials. For example, the core is formed of CdSe and the shell of CdS. The diameter of the core amounts for example to at most 70% or at most 50% or at most 30% of the total diameter of the quantum dot. Such quantum dots have a spectral distance between absorption bands and emission bands, so leading to low self-absorption. This makes it possible also to use the quantum dots in a high concentration in the converter material.

The transparent matrix material may for example be a silicone or acrylate or epoxide. The matrix material may be thermally-cured or light-cured. If the matrix material is light-curing, pixel-selective curing may take place through energization of the associated contact element.

The partitions between individual recesses advantageously form a lateral boundary for the converter material, so partially or completely preventing overflow of the converter material into adjacent recesses.

According to at least one embodiment, the semiconductor layer sequence is thinned, in the region of the recesses, to a thickness, for example average or maximum thickness, of at most 3 μm or at most 2 μm or at most 1.5 μm. The thickness may in particular be constant along the entire recess apart from roughened portions. The thickness is here understood to mean the vertical extent perpendicular to the active layer. Advantageously, such a thin semiconductor layer sequence results in few scattering or wave guidance effects, which bring about light transport parallel to the active layer. This further suppresses optical crosstalk between adjacent emission regions. In particular, due to the thin layer sequence in the region of the recesses, light is thus predominantly only outcoupled from the semiconductor layer sequence in the region in which it is also generated. Lateral light conduction is suppressed.

According to at least one embodiment, precisely one contact element is associated on a one-to-one basis with each emission region. The contact element is then preferably opposite the recess of the corresponding emission region. For example, in plan view onto the top, the recess of one emission region completely covers the associated contact element. The maximum or average or minimum lateral extent of the recess here differs from the lateral extent of the contact element for example by at most 50% or at most 30% or at most 10%.

Such an arrangement between contact element and recess of an emission region ensures that the active layer predominantly generates electromagnetic radiation only in the region of the recesses, while little or no electromagnetic radiation is generated in the region of the partitions. The partitions may then serve in plan view as regions of dark appearance between adjacent emission regions and form a boundary or a boundary region between these emission regions.

According to at least one embodiment, when viewed in plan view onto the top the emission regions are arranged in a matrix. In addition, the emission regions are surrounded in plan view onto the top for example by a continuous, uninterrupted grid of partitions. The grid mesh may for example have rectangular or hexagonal or round base areas.

According to at least one embodiment, the semiconductor chip comprises a counter contact or a plurality of counter contacts. The counter contact is the counter contact to the contact elements on the bottom and serves to remove the charge carriers injected by the contact elements from the semiconductor layer sequence or to inject oppositely charged charge carriers.

If, for example, the contact elements are formed on the bottom as contact strips extending in parallel in the region of the partitions or the recesses, counter contacts which extend transversely of or perpendicular to the contact elements may be applied on the top, for example in the region of the partitions. In plan view the contact elements and the counter contacts then for example form a grid. The individual counter contacts are then preferably also individually and mutually independently activatable. It is however also conceivable for both the contact elements and the counter contacts to be mounted on the bottom and for the semiconductor layer sequence to be energized during operation by way of through-vias.

Particularly preferably, the partitions are covered with a single contiguous and uninterrupted counter contact. The counter contact serves as a counter contact for a plurality of contact elements and in operation for contacting a plurality of emission regions. The counter contact is then for example arranged on the top of the semiconductor layer sequence. The recesses of the emission regions are preferably wholly or partially free of the counter contact, such that in the region of the recesses radiation may exit from the semiconductor layer sequence. When an emission region is in operation, a voltage is then for example applied between the counter contact and the contact element associated with the emission region. The emission regions associated with the contact element(s) then emit electromagnetic radiation.

If the counter contact is particularly thick in the region of the top, for example with a thickness of at least 5 μm or 10 μm or 20 μm, this may lead to an effective deepening of the recesses. The recesses may then appropriately be filled with more converter material or the filling level may be increased, whereby the absorption probability of the radiation generated in the active layer is also increased by the converter material.

A contiguous, uninterrupted counter contact on the top, as mentioned above, is understood for example to mean that the counter contact covers over all the partitions or the entire grid of partitions in plan view onto the top. The counter contact may thus extend in plan view, like the partitions, completely around the recesses of the emission regions. A single counter contact is preferably sufficient for contacting all the emission regions. In particular, the counter contact covers over the partitions at the top to an extent of at least 80% or at least 90% or at least 95%.

According to at least one embodiment, the counter contact comprises a light-reflecting or light-absorbing material. In particular, the counter contact may comprise or be formed from a metal such as Au, Ag, Ni, Pt, Pd, Rh or Al. It is also possible for the counter contact to comprise or be formed from a TCO, such as ITO or zinc oxide, ZnO for short.

According to at least one embodiment, the counter contact covers the partitions not only on the top, but also at side faces of the partitions. The side faces are here faces of the partitions which extend transversely of the active layer and laterally define the recesses. In particular, the side faces of all the partitions may be covered to an extent of at least 80% or 90% or 95% with the counter contact. The counter contact then preferably ensures not only contacting of the semiconductor layer sequence, but also that the electromagnetic radiation of an emission region generated or converted in the region of the recess cannot pass through the partitions to adjacent emission regions, but rather is previously reflected or absorbed by the side walls of the partitions. This further increases the contrast ratio between adjacent emission regions or pixels.

According to at least one embodiment, the bottom of the semiconductor layer sequence is free of contact elements in the region of the partitions. In this way, it is advantageously ensured that the active layer generates little or no radiation during operation in the regions of the partitions. For example, to this end an insulating layer, for example a silicon oxide such as SiO₂, is applied to the bottom in the region of the partitions. Advantageously, this insulating layer forms with the contact elements mounted in the region of the recesses a flat face remote from the semiconductor layer sequence, i.e. the contact elements and the insulating layer terminate flush with one another in side view. Such a flat layer formed of contact elements and insulating layer is particularly advantageous for application of a carrier to the bottom for example using wafer bonding methods, such as direct bonding, in which a wafer is joined mechanically firmly to a semiconductor layer sequence by way of van der Waals forces and/or hydrogen bridge bonds and/or covalent bonds, such that no additional intermediate layers are necessary.

According to at least one embodiment, a common active matrix element is applied at the bottom to a plurality of contact elements. The active matrix element serves for example in selective electrical activation of the individual contact elements. The active matrix element for example comprises a plurality of transistors, for instance thin film transistors or CMOS transistors, which have the same, preferably matrix-like arrangement as the contact elements on the bottom. The transistors may for example be mounted on a substrate, for example a glass substrate or a printed circuit board or an Si wafer. In this case, a contact element and thus an emission region of the semiconductor layer sequence is unambiguously associated with each transistor. Furthermore, power supply connections on the active matrix element are for example unambiguously associated with each emission region of the semiconductor layer sequence. In particular, the active matrix element may be joined by way of a direct bonding method to the semiconductor layer sequence. The active matrix element not only serves for example in electrical activation of the contact elements, but rather also has a mechanical load-bearing function for the semiconductor layer sequence. In particular, the active matrix element thus serves as a carrier and renders the entire semiconductor chip self-supporting and mechanically stable.

Alternatively, the active matrix element may also be produced or deposited directly on the contact elements of the semiconductor layer sequence, for example if thin film transistors are used for the active matrix element. In this case, the semiconductor chip may comprise an additional carrier, which ensures mechanical stabilization of the semiconductor layer sequence and of the active matrix element.

According to at least one embodiment, the lateral extent of the recesses of the emission regions decreases from the top in the direction of the active layer. The recesses preferably further comprise a base surface which extends parallel to the active layer. The average distance between base surface and active layer is then preferably less than the height of the partitions.

The base surface of the recesses may then serve as a radiation outcoupling face for outcoupling the electromagnetic radiation generated in the region of the recess from the semiconductor layer sequence. To this end, the base surface may for example additionally comprise intentionally introduced roughening, for example with a roughness of ≧200 nm. Such roughening on the base surface may increase the outcoupling efficiency from the base surface of the recess. Alternatively, it is however also possible for the base surfaces to be smoothed in the region of the recesses and to have a roughness of ≦200 nm or ≦100 nm or ≦50 nm. Although such a smoothed base surface would reduce the outcoupling efficiency from the base surface, on the other hand such a smooth surface results in less scattering, which further reduces optical crosstalk between adjacent emission regions.

The preferably continuous, uninterrupted base surface is laterally surrounded for example completely by the side faces of the partitions, wherein the side faces may reflect or absorb the radiation emitted from the base surface. The base surfaces are preferably partially or completely free of the counter contact.

According to at least one embodiment, when viewed from the active layer the partitions taper to a point in the direction of the top, such that a width of the partitions in the region of the vertex amounts to at most 1/10 or at most 1/50 or at most 1/100 of the maximum width of the partitions, in particular the lateral extent of the vertex may be negligibly small compared with the maximum extent of the partition. Such a configuration of the partitions is in particular advantageous for the production method described further below.

According to at least one embodiment, a protective layer, which protects the counter contact from external influences, is applied to the sides of the counter contact remote from the semiconductor layer sequence. The protective layer covers the counter contacts at least in part, in particular completely. For example, the protective layer comprises or consists of Al₂O₃, SiO₂, SiNₓ, SiOₓN_{y}, TaNₓ, TiO₂, parylenes, polyurethane coating materials, or epoxy-containing coating materials.

According to at least one embodiment, the recesses of the emission regions have a lateral extent of at least 1 μm or at least 5 μm or at least 10 μm. Alternatively or in addition, the lateral extent of the recesses is ≦300 μm or ≦100 μm or ≦50 μm. The lateral extent of the recesses is here understood to refer in particular to the maximum lateral extent or the maximum lateral extent of the base surfaces of the recesses.

According to at least one embodiment, the maximum width of the partitions between two recesses is at least 10% or at least 20% or at least 25% of the lateral extent of the recesses of the emission regions. Alternatively or in addition, the maximum width of the partitions is ≦100% or ≦50% or ≦30% of the lateral extent of the recesses.

According to at least one embodiment, the thickness of the semiconductor layer sequence in the region of the partitions is at least 5 μm or at least 6 μm or at least 7 μm. Alternatively or in addition, the thickness of the semiconductor layer sequence in the region of the partitions is ≦12 μm or ≦10 μm or ≦8 μm.

According to at least one embodiment, the side faces of the partitions extend obliquely relative to the active layer and form with the active layer for example an angle of at least 30° or at least 60° or at least 80°. Alternatively or in addition, the angle between the side faces of the partitions and of the active layer is at most 90° or at most 80° or at most 60°.

According to at least one embodiment, the active layer of the semiconductor layer sequence generates radiation in the blue region of the spectrum or the UV region of the spectrum when in operation. To this end, the semiconductor layer sequence is based for example on a nitride compound semiconductor material.

According to at least one embodiment, the semiconductor chip has a plurality of pixel groups. Each pixel group is formed for example from at least three emission regions arranged adjacent one another. For example, in each pixel group a recess of a first emission region is filled with a first, for example red converter material and a further recess of a second emission region with a second, for example green converter material. A recess of a third emission region for example comprises either a blue converter material or is free of a converter material. Overall, in this way each of the pixel groups may serve as a red-green-blue emitting unit. Since the emission regions may preferably be activated individually and mutually independently, the red-green-blue emitting emission regions of each pixel group may also be activated individually and mutually independently. In this way, a color-emitting, pixelated display may be produced.

According to at least one embodiment, the pixel groups are arranged in a matrix on the top of the semiconductor layer sequence. The three emission regions of each pixel group are in this case arranged for example in a row.

Furthermore, a projection device is provided which comprises a semiconductor chip described here. Downstream of the semiconductor chip an optical system may be arranged, i.e. a construct of optical elements such as lenses, mirrors, prisms, deflecting elements and diaphragms. By way of the optical system, a real or virtual image of an image emitted by the semiconductor chip may then be produced and represented on a projection surface.

A method for producing a semiconductor chip is additionally provided. The method may in particular be suitable for producing a semiconductor chip as described above. Features of the semiconductor chip are therefore also disclosed for the method and vice versa.

According to at least one embodiment of the method, in a step A a semiconductor layer sequence is grown on a growth substrate. The growth substrate may for example be a silicon substrate or a sapphire substrate. A buffer layer sequence may also be arranged between the semiconductor layer sequence and the growth substrate, to achieve better growth conditions The grown semiconductor layer sequence in particular comprises an active layer for generating electromagnetic radiation.

According to at least one embodiment, in a further step B contact elements are applied to a bottom of the semiconductor layer sequence remote from the growth substrate.

According to at least one embodiment, in a step C a carrier is applied to the bottom of the semiconductor layer sequence.

According to at least one embodiment, in a step D the growth substrate is partially or completely detached, for example by means of an etching process or a polishing process or a laser process. In the process, a top of the semiconductor layer sequence lying opposite the bottom is preferably exposed.

According to at least one embodiment, in a step E emission regions are formed in the semiconductor layer sequence. This takes place in particular through the introduction of recesses into the semiconductor layer sequence. In the process, the recesses extend from the exposed top in the direction of the active layer but preferably do not penetrate the active layer. Moreover, on formation of the recesses partitions consisting of the semiconductor layer sequence remain, which in plan view onto the top form a contiguous web completely surrounding the respective recess. The recesses are formed for example using an etching process and with a patterned mask.

According to at least one embodiment, in a step F a patterned counter contact is applied to the top, such that the partitions of the semiconductor layer sequence are covered at least in part by the counter contact, but the recesses remain at least in part free of the counter contact.

According to at least one embodiment, steps A to F are carried out in the stated sequence. Alternatively, step F may also be carried out before step E. The patterned counter contact may then for example serve as an etching mask for introduction of the emission regions.

According to at least one embodiment, in step E the partitions are formed such that they taper to a point in the direction of the top when viewed from the active layer. In step F an uninterrupted, contiguous counter contact layer may then be applied over the entire surface of the sides of the semiconductor layer sequence remote from the carrier. Subsequently, an uninterrupted, contiguous protective layer is then preferably applied over the entire surface of the sides of the counter contact layer remote from the carrier. In a subsequent step, a directional etching method may then be used, in which the protective layer is etched away in the region of side faces of the partitions at a lower etching rate than in the region of base surfaces of the recesses. The more extensive etching away in the region of the base surfaces is automatic, since a directional etching method is used in which the base surfaces of the recesses preferably extend perpendicular to a main etching direction of the etching method, whereas the side faces extend at an angle of <90° to the main etching direction. It may thereby be ensured that, after the directional etching method, the side faces are still completely covered by a thinned protective layer, whereas the base surfaces are partially or completely free of the protective layer. The counter contact layer is then exposed in the region of the base surfaces. In a next step, a further etching method may then be used, in which the protective layer on the side walls serves as a mask, and in which the counter contact layer is partially or completely removed in the region of the base surface of the recesses.

The partitions tapering to a point thus enable a self-adjusting method for applying counter contacts to the partitions. It is possible to dispense with lithography or mask producing methods, in which certain adjusting tolerances have also to be taken into account.

According to at least one embodiment, in a step G one or more recesses in the semiconductor layer sequence are partially or completely filled with a converter material. Filling may proceed for example by means of an inkjet printing process or an aerosol jet process or dispensing or screen printing.

An optoelectronic semiconductor chip described here and a method described here for producing an optoelectronic semiconductor chip are explained in greater detail below with reference to exemplary embodiments. Elements which are the same in the individual figures are indicated with the same reference numerals. The relationships between the elements are not shown to scale, however, but rather individual elements may be shown exaggeratedly large to assist in understanding.

In the figures:

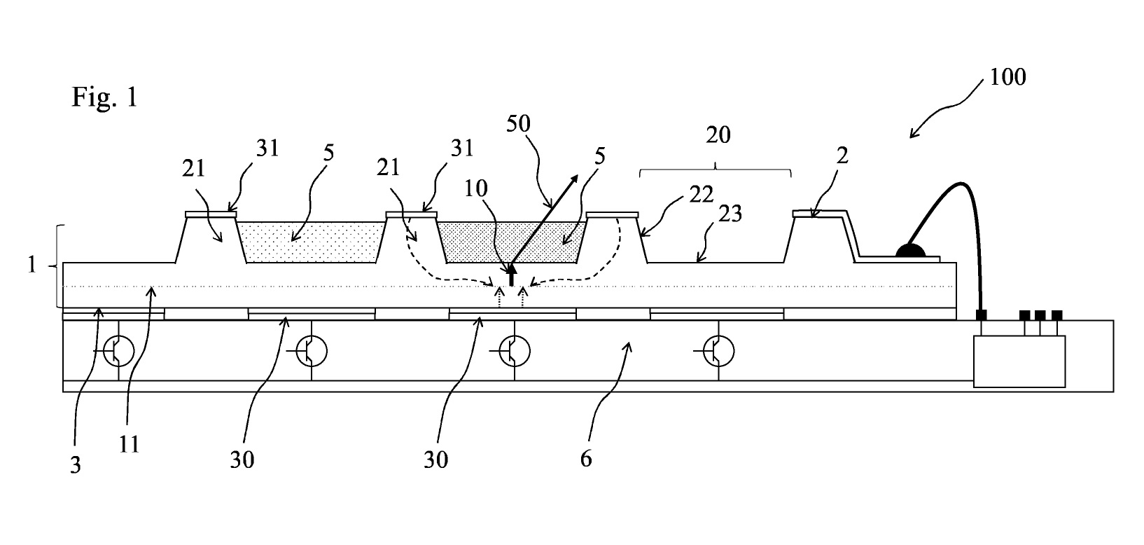

FIGS. 1 to 8 are schematic representations of exemplary embodiments of optoelectronic semiconductor chips described here,

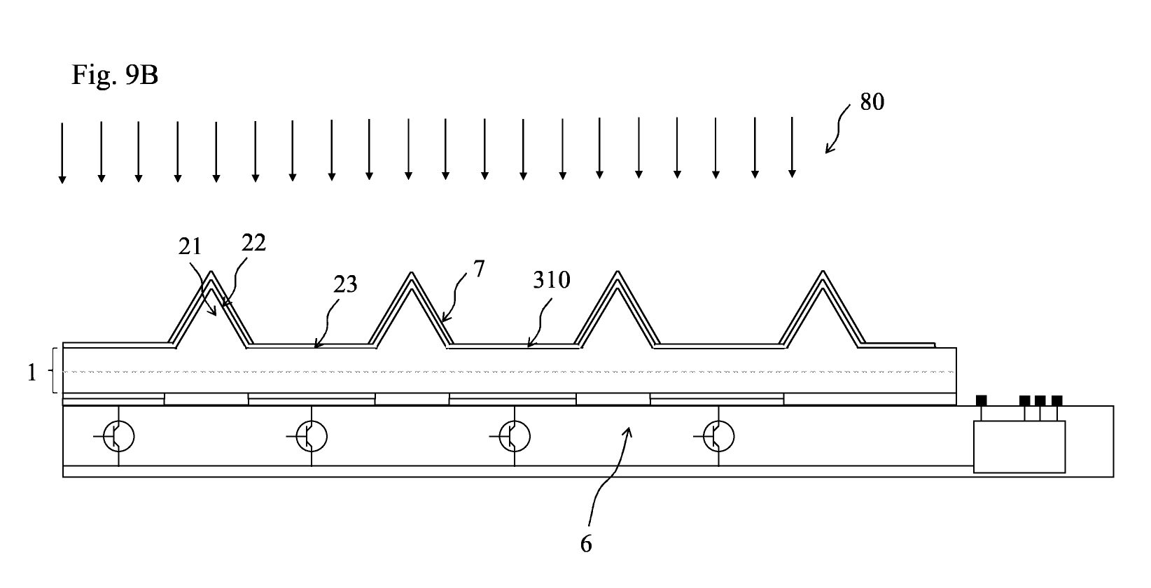

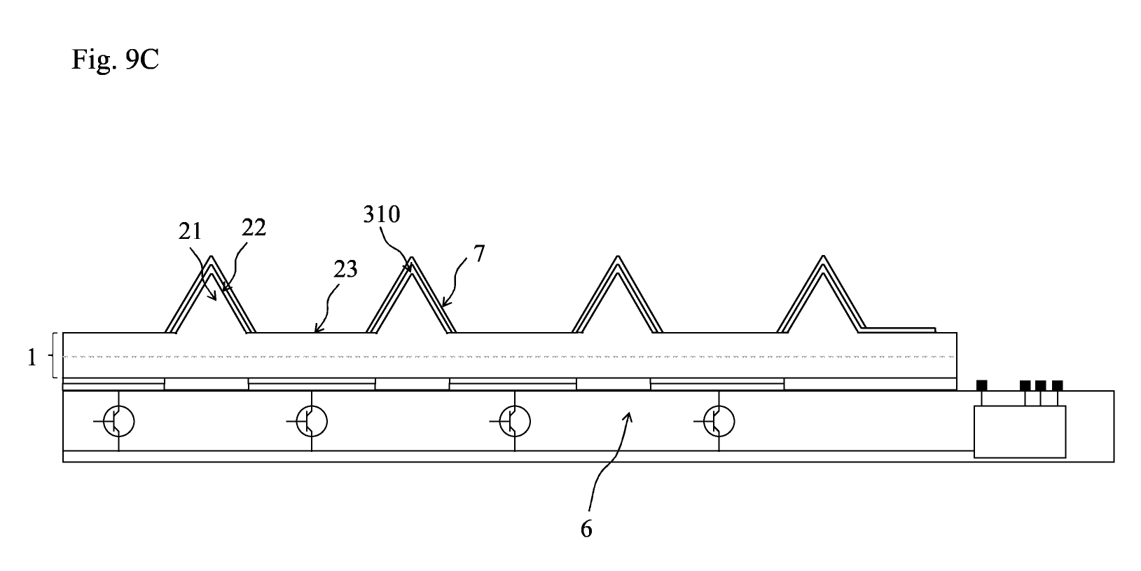

FIGS. 9A to 9C are schematic representations of method steps of a method described here for producing an optoelectronic semiconductor chip.

FIG. 1 shows a semiconductor chip 100 with a carrier in the form of an active matrix element 6, to which a semiconductor layer sequence 1 has been applied. The semiconductor layer sequence 1 further comprises an active layer 11 for generating electromagnetic radiation of a first wavelength 10. The semiconductor layer sequence 1 is based for example on InGaAlN, while the active layer 11 is for example a pn junction. Furthermore, the semiconductor layer sequence 1 comprises a top 2, which extends parallel to the active layer 11 and which comprises the regions of the semiconductor layer sequence 1 furthest from the active layer 11. Opposite the top 2 the semiconductor layer sequence 1 comprises a bottom 3, which likewise extends parallel to the active layer 11 and likewise comprises the regions of the semiconductor layer sequence 1 furthest from the active layer 11. The bottom 3 faces the active matrix element 6.

A plurality of recesses has moreover been introduced into the semiconductor layer sequence 1, these extending from the top 2 in the direction of the active layer 11 but not piercing the active layer 11. In the present case, in the cross-sectional view shown the recesses take the form of upside-down truncated cones or pyramids, wherein a base surface 23 of each recess extends parallel to the active layer 11. The individual recesses are separated and spaced from one another in the lateral direction parallel to the active layer 11 by partitions 21. The partitions 21 here form part of the semiconductor layer sequence 1, such that the entire semiconductor chip 100 comprises a single contiguous semiconductor layer sequence 1 formed in one piece.

Side faces 22 of the partitions 21 extend obliquely to the active layer 11 and laterally define the recesses in the semiconductor layer sequence 1.

Moreover a counter contact 31, for example of Al, has been applied to plateau-like vertices of the partitions 21 in the region of the top 2, which counter contact serves in electrical contacting of the semiconductor layer sequence 1. In the present case shown in FIG. 1, the side walls 22 of the partitions 21 are free of the counter contact 31. The counter contact 31 is electrically connected laterally by way of a bonding wire to the active matrix element 6.

Between the active matrix element 6 and the bottom 3 of the semiconductor layer sequence 1, moreover, contact elements 30 are mounted in the region of the recesses. In plan view onto the top 2, the contact elements 30 are completely covered over by the recess or the base surface 23 of the recess. A single contact element 30 is associated on a one-to-one basis with each recess.

Furthermore, an insulation layer consisting for example of silicon oxide is mounted between the contact elements 30 in the region of the partitions 21. The insulation layer is preferably arranged on the bottom 3 throughout the region of the partitions 21.

Furthermore, in FIG. 1 the insulation layer terminates flush with the contact elements 30 on a side remote from the semiconductor layer sequence 1, such that the insulation layer and the contact elements 30 together form a layer with flat major faces. The active matrix element 6 is applied for example by means of a direct bonding method to one of the flat major faces.

The contact elements 30 are constructed in the example of FIG. 1 from two layers stacked on one another, wherein the layer facing the active layer 11 is a mirror layer for example of Ag. The layer of the contact element 30 remote from the active layer 11 preferably serves as a bonding layer to the active matrix element 6 and consists for example of Ni or Al or Cu.

In the example of FIG. 1 the individual contact elements 30 are electrically connected via individually activatable transistors, for example thin film transistors, to a shift register likewise arranged in the active matrix element 6. This ensures that the individual contact elements 30 may be individually and mutually independently activated or energized. As shown in FIG. 1, when a contact element 30 is activated charge carriers are injected by the contact element 30 in the direction of the active layer 11 into the semiconductor layer sequence 1. From the counter contact 31 mounted on the top 2, which serves as a common counter contact for all the contact elements 30 on the bottom 3, oppositely charged charge carriers are injected via the partitions 21 in the direction of the active layer 11. On recombination of the charge carriers in the active layer 11, radiation preferably arises only in the region around the respectively activated contact element 30. The radiation of a first wavelength 10 generated then exits from the semiconductor layer sequence 1 via the base surface 23.

In this way, the semiconductor layer sequence 1 is subdivided into a multiplicity of emission regions 20 arranged laterally adjacent one another. The emission regions 20 are regions via which electromagnetic radiation is outcoupled from the semiconductor layer sequence 1, and which are perceptible to an observer, when viewed in plan view onto the top 2, as separate picture elements or pixels. The partitions 21 with the counter contact elements 31 mounted thereon are in each case arranged between the emission regions 20. Because no or little radiation is generated in the region of the partitions 21 due to the insulation layer and because a counter contact 31 has been applied to the partitions 21, virtually no radiation exits from the semiconductor layer sequence 1 via the partitions 21. In plan view, the partitions 21 thus form a possibly dark optical boundary between adjacent emission regions 20. Furthermore, due to the configuration of the semiconductor chip 100 in FIG. 1, the lateral extent of each emission region 20 is defined by the lateral extent of the associated recess.

In FIG. 1, moreover, some of the recesses are filled with a converter material 5. The converter material 5 for example comprises luminescent organic molecules or quantum dots, which are introduced in a transparent matrix material of a silicone or acrylate. The light of the first wavelength 10 emitted in the respective recess via the base surface 23 is converted by way of the converter material 5 at least in part into light of a second wavelength 50 different from the first wavelength 10. Blue light emitted by the active layer 11 when the semiconductor chip 100 is in operation is for example converted by the converter material 5 into red or green light. The recesses serve in particular as molds for filling with the converter material 5. The partitions 21 prevent converter material 5 from overflowing into adjacent recesses.

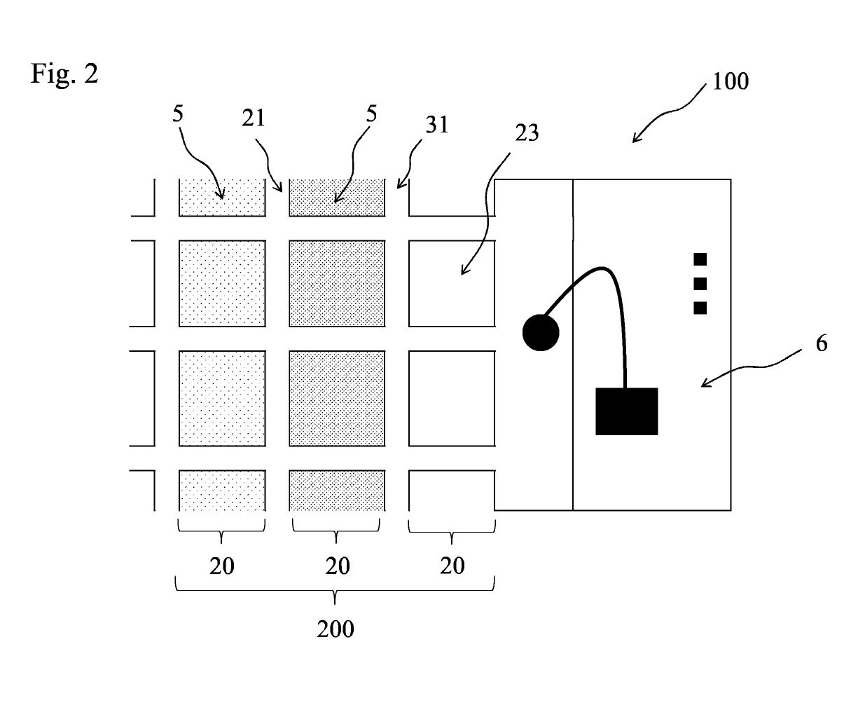

The exemplary embodiment of FIG. 2 shows a plan view onto the top 2 of a semiconductor chip 100. The recesses in the semiconductor layer sequence 1 in the present case have a rectangular basic shape and are arranged in a regular rectangular matrix pattern. The partitions 21 between the recesses form a rectangular-mesh grid, which completely surrounds the recesses in the semiconductor layer sequence 1 in uninterrupted manner. The contact element 31 has been applied fully to the partitions 21, i.e. the contact element 31 reproduces the grid of the recesses and is likewise of uninterrupted and continuous configuration. In particular, the counter contact 31 is formed between a plurality of recesses and laterally completely surrounds the recesses.

In the example of FIG. 2 it is moreover apparent that in each case three neighboring emission regions 20 are combined into a pixel group 200. The pixel groups 200 are likewise arranged in a matrix on the top 2. In each pixel group 200 a first recess is filled with a red converter material 5 and a second recess with a green converter material 5. The third recess is free of a converter material. If the active layer 11 of the semiconductor layer sequence 1 emits blue light, for example, this is converted by the red converter material at least in part into red light and by the green converter material at least in part into green light. Blue light is emitted via the third recess. Overall, each pixel group 200 thus forms a blue-red-green emitting unit of three different colored pixels. Such a configuration results in the semiconductor chip 100 of FIG. 2 taking the form, for example, of a polychromatically emitting pixel display.

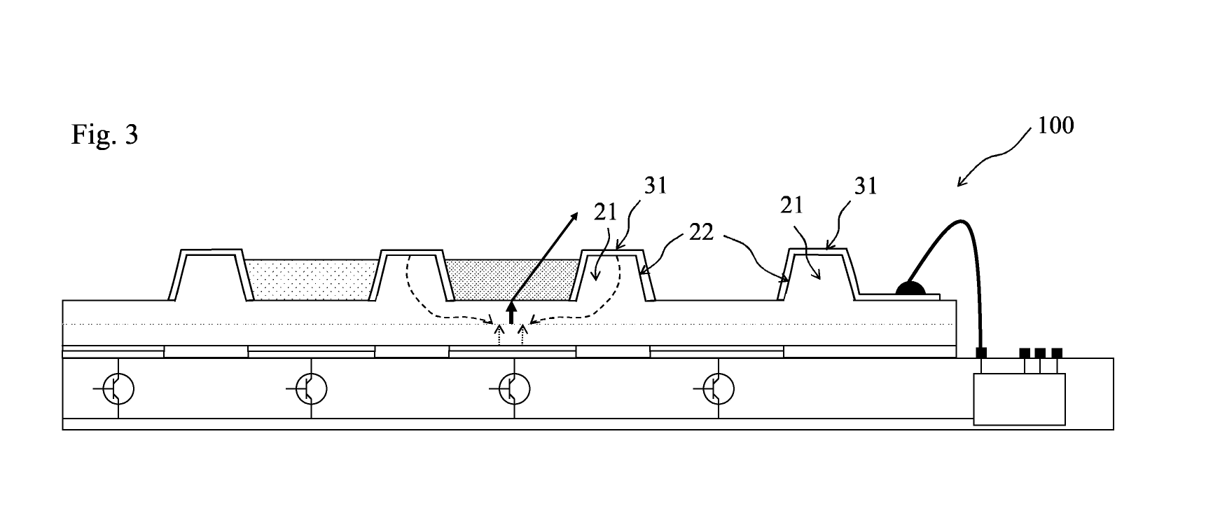

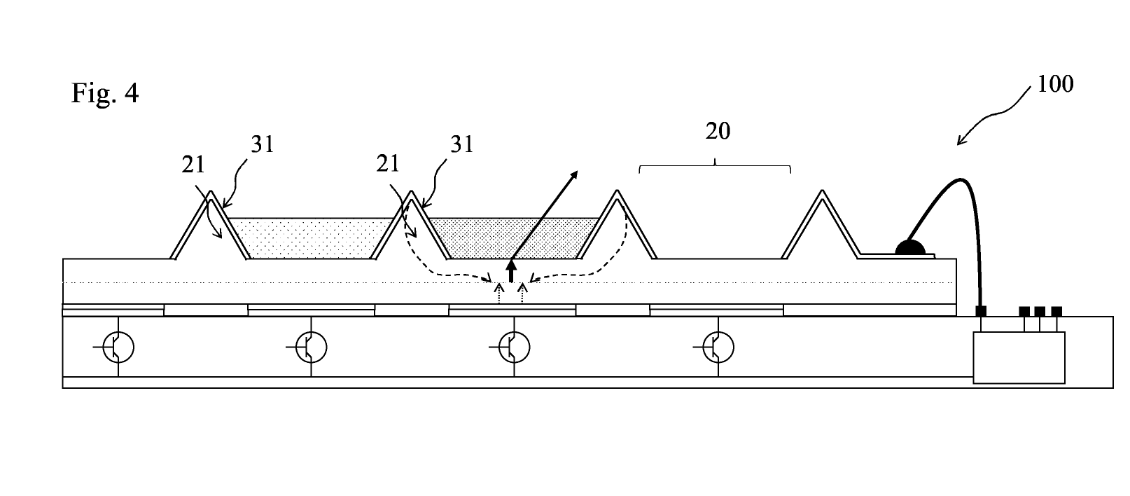

The exemplary embodiment of FIG. 3 shows a similar semiconductor chip 100 to FIG. 1. In contrast to FIG. 1, however, in FIG. 3 side walls 22 of the partitions 21 are also completely covered with the counter contact 31. The counter contact 31 in this case preferably comprises a reflective material such as Ag or Al. Radiation which exits from the semiconductor layer sequence 1 from the base surface 23 of the recesses cannot then enter an adjacent recess through the partitions 21. The completely covered partitions 21 therefore ensure a particularly high contrast ratio between adjacent emission regions 20.

Unlike in the exemplary embodiment of FIG. 3, in the exemplary embodiment of FIG. 4 each partition 21 is configured such that the partitions 21 taper to a point in the direction of the top 2 when viewed from the active layer 11. The lateral extent of the partitions 21 in the region of the top is then for example negligibly small in comparison with the maximum lateral extent of the partitions 21. In the exemplary embodiment of FIG. 4 too, the side faces 22 of the partitions 21 are completely covered with the counter contact 31.

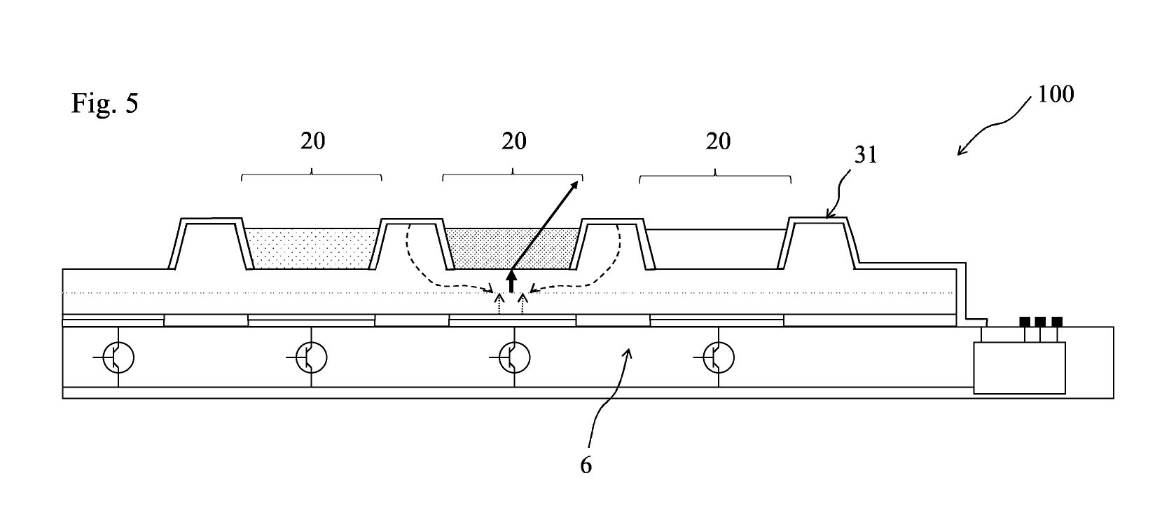

The exemplary embodiment of FIG. 5 differs from the exemplary embodiment of FIG. 3 in that the counter contact 31 is not contacted with the active matrix element 6 by way of a bonding wire. Instead, the counter contact 31 here takes the form of a layer which projects laterally beyond the semiconductor layer sequence 1 and is guided over a side face of the semiconductor layer sequence 1 as far as the active matrix element 6. There, the counter contact 31 is connected electrically conductively with a shift register of the active matrix element 6. Unlike what is shown in FIG. 5, the counter contact 31 is insulated from the semiconductor layer sequence 1 preferably at least in the region of the side face of the semiconductor layer sequence 1 by way of an insulation layer, such that during operation no short circuit is generated in the semiconductor layer sequence 1 by the counter contact 31.

Moreover, in FIG. 5 a recess, which was free of a converter material 5 in the previous exemplary embodiments, has now been filled with a transparent filler material. When operated as intended, the transparent filler material does not convert the light emitted by the active layer 11 or does so only to a very limited extent. The transparent filler material here serves for example to protect the semiconductor layer sequence 1 from external influences in the region of the recesses. The transparent filler material may be the same material as is also used for the above-stated transparent matrix material.

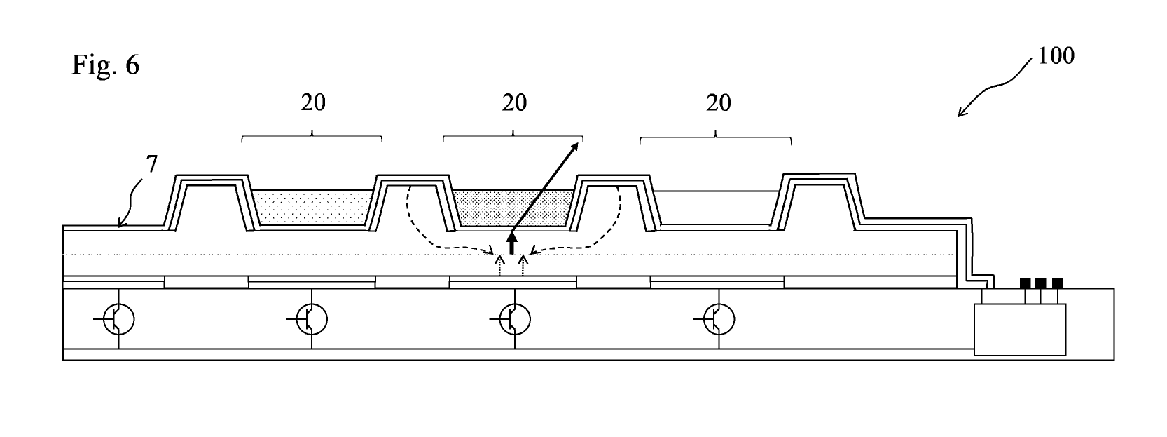

Unlike in the exemplary embodiment of FIG. 5, in the exemplary embodiment of FIG. 6 a protective layer 7 has additionally been applied to the semiconductor layer sequence 1. The protective layer 7 is here at least in part in direct contact with the semiconductor layer sequence 1 in the region of the recesses and has been arranged between the semiconductor layer sequence 1 and the converter material 5. For example, the protective layer 7 completely covers the base surfaces 23 of the recesses. Moreover, the protective layer 7 has also been applied to the side walls 22 and to the top of the partitions 21. The protective layer 7 then preferably completely covers over the counter contact 31 applied to the partitions 21. The protective layer 7 protects the counter contact 31 from external influences, in particular from oxidation or from ingress of moisture. In FIG. 6 the protective layer 7 is configured for example as a contiguous, uninterrupted protective layer 7 applied over the entire surface.

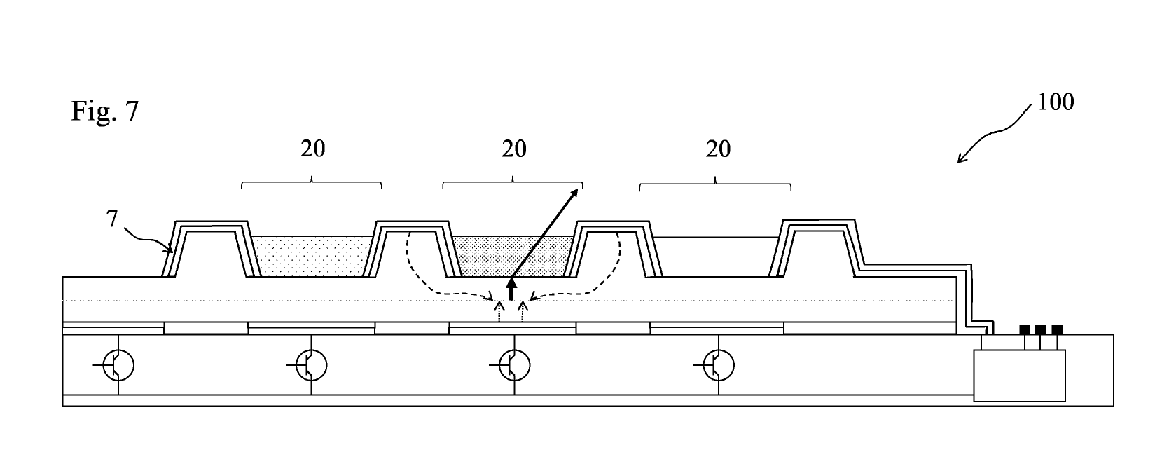

As in FIG. 6, in the exemplary embodiment of FIG. 7 each partition 21 is completely covered by the protective layer 7.

However, in FIG. 7 the base surfaces 23 of the recesses are free of the protective layer 7. Such a configuration may be achieved, for example, in that prior to filling of the recesses with the converter material 5 the protective layer 7 is removed in the region of the recesses using an etching method.

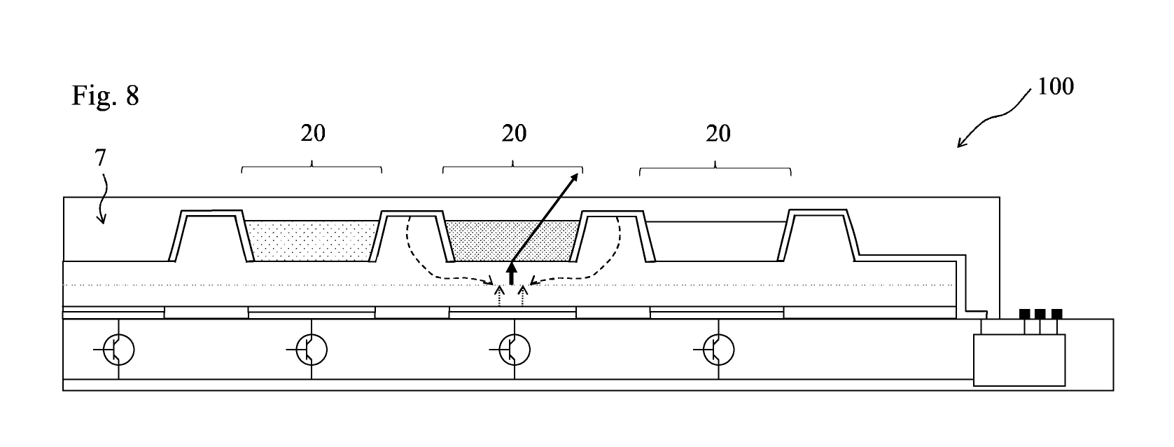

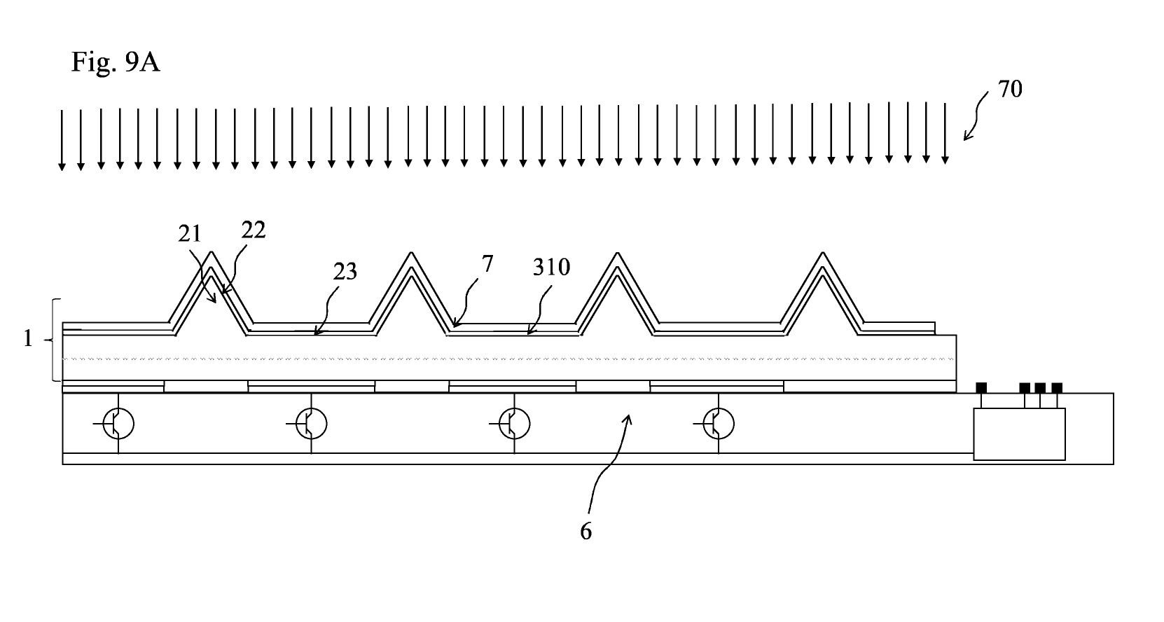

In FIG. 8 the protective layer 7 is not arranged, as in the exemplary embodiments of FIG. 6, between the converter material 5 and the semiconductor layer sequence 1, but rather the protective layer 7 is here applied as a potting compound over the entire semiconductor layer sequence 1. The protective layer 7 is thus arranged on the side of the converter material 5 remote from the active layer 11.

In particular, the protective layer 7 completely covers over all the recesses, all the partitions 21 and all the side faces of the semiconductor layer sequence 1.

FIG. 9A shows a method step for producing a semiconductor chip 100 described here. In the method step a semiconductor layer sequence 11 has already been applied to an active matrix element 6, which is not the growth substrate for the semiconductor layer sequence 1. Furthermore, recesses have already been introduced from the top 2 into the semiconductor layer sequence 1 for example by way of an etching method. The recesses have here been introduced in such a way that the remaining partitions 21, which completely surround the recesses, have a cross-sectional shape that tapers to a point. Furthermore, a contiguous, uninterrupted counter contact layer 310 has already been applied to the side of the semiconductor layer sequence 1 remote from the active matrix element 6 over the entire surface of the semiconductor layer sequence 1. The counter contact layer 310 completely covers the base surfaces 23 of the recesses and all the side faces 22 of the partitions 21. Furthermore, a protective layer 7 has been applied to the side of the counter contact layer 310 remote from the active matrix element 6, which protective layer is likewise contiguous and uninterrupted and has been applied over the entire surface of the counter contact layer 310. The protective layer 7 consists for example of a silicon oxide, such as SiO₂, while the counter contact layer 310 consists for example of Ag.

FIG. 9A further shows how the protective layer 7 is treated with a directional etching method 70, such as reactive-ion etching, from a side remote from the active matrix element 6. The directional etching method 70 allows the protective layer 7 to be removed to a greater extent in the region of the base surface 23 of the recesses than on the side faces 22 of the partitions 21.

A possible result of this directional etching method 70 is shown in FIG. 9B. In FIG. 9B the protective layer 7 has been completely removed in the region of the base surfaces 23 of the recesses. Since the side faces 22 extend at an angle other than 90° to the main etching direction of the directional etching method 70, it is possible for the protective layer 7 not to be simultaneously completely removed in the region of the side faces 22. The side faces 22 of the partitions 21 are thus still completely covered over by the protective layer 7.

FIG. 9B moreover shows how a further etching method 80, for example a wet chemical etching method, is carried out from a side remote from the active matrix element 6.

In the etching method 80 the protective layer 7 on the side walls 22 now serves as a mask structure, which is barely or only slightly attacked by the further etching method 80. To this end, the counter contact layer 310 is now partially or completely removed by the further etching method 80 in the region of the recesses 23 which is free of the protective layer 7.

The result of this further etching method 80 is shown in FIG. 9C, in which the base surfaces 23 of the recesses are completely free both of the counter contact layer 310 and of the protective layer 7. The protective layer 7 and the counter contact layer 310 remain solely on the side walls 22 of the partitions 21.

The method depicted in FIGS. 9A to 9C thus allows the partitions 21 to be provided with a common patterned counter contact 31, without complex mask forming and lithography methods being needed to pattern the counter contact 31. Instead, the method here is a self-adjusting method, which makes use of the fact that the partitions 21 taper to a point.

The invention described here is not restricted by the description given with reference to the exemplary embodiments. Rather, the invention encompasses any novel feature and any combination of features, including in particular any combination of features in the claims, even if this feature or this combination is not itself explicitly listed in the claims or exemplary embodiments.

This patent application claims priority from German patent application 10 2014 112 551.7, the disclosure content of which is hereby included by reference.

### LIST OF REFERENCE SIGNS

1 Semiconductor layer sequence
2 Top
3 Bottom
5 Converter material
6 Active matrix element
7 Protective layer
10 Radiation of a first wavelength
11 Active layer
20 Emission region
21 Partition
22 Side faces of the partition 21
23 Base surface of the recess
30 Contact element
31 Counter contact
50 Radiation of a second wavelength
100 Semiconductor chip
200 Pixel group

1. Optoelectronic semiconductor chip comprising
a semiconductor layer sequence with a top, a bottom opposite the top and an active layer for generating electromagnetic radiation of a first wavelength, wherein the semiconductor chip is free of a growth substrate for the semiconductor layer sequence,
a plurality of contact elements arranged on the bottom, which are individually and mutually independently electrically activatable when operated as intended, wherein
the semiconductor layer sequence is subdivided into a plurality of emission regions arranged adjacent one another in the lateral direction, which emission regions are configured to emit radiation when in operation,
at least one of the contact elements is associated with each of the emission regions,
each emission region comprises a recess in the semiconductor layer sequence, which extends from the top in the direction of the active layer,
in plan view onto the top, the recess of each emission region is completely surrounded by a contiguous web of partitions, wherein the partitions are formed from the semiconductor layer sequence and wherein the partitions form boundaries between adjacent emission regions.

2. Optoelectronic semiconductor chip according to claim 1, wherein
the recess of at least one emission region is filled at least in part with a converter material,
the converter material converts the radiation of the first wavelength generated when the relevant emission region is in operation at least partly into radiation of a second wavelength different from the first wavelength,
the partitions form a lateral boundary for the converter material.

3. Optoelectronic semiconductor chip according to claim 1,
wherein in the region of the recesses of the emission regions, the semiconductor layer sequence has a thickness measured perpendicular to the top of at most 3 μm.

4. Optoelectronic semiconductor chip according to claim 1, wherein
precisely one contact element is associated on a one-to-one basis with each emission region,
the contact element belonging to an emission region is opposite the recess,
the recesses of the emission regions completely cover over the associated contact elements when viewed in plan view,
the lateral extents of the recesses of the emission regions differ by at most 50% from the lateral extents of the associated contact elements.

5. Optoelectronic semiconductor chip according to claim 1, wherein
when viewed in plan view onto the top, the emission regions are arranged in a matrix,
when viewed in plan view onto the top, the emission regions are surrounded by a grid of partitions.

6. Optoelectronic semiconductor chip according to claim 1, wherein
the partitions are covered with a contiguous counter contact, which is arranged on the top of the semiconductor layer sequence and in operation serves in contacting a plurality of emission regions,
the recesses of the emission regions are at least partly free of the counter contact,
to operate an emission region, a voltage is applied between the counter contact and the contact element associated with the emission region.

7. Optoelectronic semiconductor chip according to claim 1, wherein
the counter contact comprises a light-reflecting or light-absorbing material,
the counter contact covers the partitions not only on the top but also on side faces of the partitions, such that the individual emission regions are optically separated from one another by the partitions.

8. Optoelectronic semiconductor chip according to claim 1,
wherein the bottom of the semiconductor layer sequence is free of contact elements in the region of the partitions, such that in operation the active layer generates little or no radiation in the regions of the partitions.

9. Optoelectronic semiconductor chip according to claim 1,
wherein a common active matrix element which serves in selective electrical activation of the individual contact elements is applied on the bottom to a plurality of contact elements.

10. Optoelectronic semiconductor chip according to claim 1, wherein
the lateral extent of the recesses of the emission regions decreases from the top in the direction of the active layer,
the recesses of the emission regions each have a base surface which extends parallel to the active layer.

11. Optoelectronic semiconductor chip according to claim 1,
wherein the partitions taper to a point in the direction of the top when viewed from the active layer, such that a width of the partitions in the region of the top amounts to at most 1/10 of the maximum width of the partitions.

12. Optoelectronic semiconductor chip according to at least claim 6,
wherein a protective layer is applied to the sides of the counter contact remote from the semiconductor layer sequence, which protective layer protects the counter contact from external influences.

13. Optoelectronic semiconductor chip according to claim 1, wherein
the recesses of the emission regions have a lateral extent of between 1 μm and 300 μm,
the maximum width of the partitions amounts to between 10% and 100% inclusive of the lateral extent of the recesses of the emission regions,
the thickness of the semiconductor layer sequence in the region of the partitions amounts to between 5 μm and 12 μm inclusive.

14. Optoelectronic semiconductor chip according to claim 1, wherein
the counter contact comprises or consists of at least one of the following materials: Ag, Au, Pt, Pd, Ni, Rh, Al, TCO;
the converter material comprises or consists of at least one transparent matrix material with at least one light-converting luminescent material introduced therein, wherein the luminescent material comprises or consists of organic molecules and/or luminescent polymers and/or quantum dots;
the protective layer comprises or consists of at least one of the following materials: Al₂O₃, SiO₂, SiNₓ, SiOₓN_{y}, TaNₓ, TiO₂, parylenes, PU coating materials, EP coating materials.

15. Optoelectronic semiconductor chip according to claim 1, wherein
the active layer of the semiconductor layer sequence generates radiation in the blue region of the spectrum when in operation,
the semiconductor chip comprises a plurality of pixel groups, wherein each pixel group comprises three emission regions arranged adjacent one another,
in each pixel group a recess of a first emission region is filled with a red converter material and a recess of a second emission region is filled with a green converter material and a third emission region is free of a converter material, such that each pixel group forms a red-green-blue emitting unit,
the pixel groups are arranged in a matrix on the top.

16. Method for producing an optoelectronic semiconductor chip, comprising the following steps:
A) growing a semiconductor layer sequence on a growth substrate, wherein the semiconductor layer sequence comprises an active layer for generating electromagnetic radiation;
B) mounting contact elements on a bottom, remote from the growth substrate, of the semiconductor layer sequence;
C) applying a carrier to the bottom;
D) detaching the growth substrate, wherein a top of the semiconductor layer sequence opposite the bottom is exposed;
E) forming emission regions by forming recesses in the semiconductor layer sequence, wherein each recess extends from the top in the direction of the active layer, wherein partitions consisting of the semiconductor layer sequence remain around each recess, which partitions form a contiguous web completely surrounding the recess when viewed in plan view onto the top and wherein the lateral extent of the recesses of the emission regions decreases from the top in the direction of the active layer.

17. Method for producing an optoelectronic semiconductor chip according to claim 16, wherein
the partitions taper to a point in the direction of the top when viewed from the active layer;
in a step F) an uninterrupted, contiguous counter contact layer is applied over the entire surface of the sides of the semiconductor layer sequence remote from the carrier;
subsequently, an uninterrupted, contiguous protective layer is applied over the entire surface of the sides of the counter contact layer remote from the carrier;
thereafter, a directional etching method is used, in which the protective layer is etched away in the region of base surfaces of the recesses to a greater extent than in the region of side faces of the partitions, such that, after the directional etching method, the side faces are completely covered by the protective layer and the base surfaces are at least partly free of the protective layer;
subsequently, a further etching method is used, in which the protective layer acts as a mask, and in which the counter contact layer is at least partially removed in the region of the base surfaces of the recesses.

18. Method for producing an optoelectronic semiconductor chip according to claim 16,
wherein in a step G) the recesses in the semiconductor layer sequence are at least partly filled with a converter material using one of the following methods: inkjet printing, aerosol jetting, dispensing, screen printing.

19. Optoelectronic semiconductor chip comprising
a semiconductor layer sequence with a top, a bottom opposite the top and an active layer for generating electromagnetic radiation of a first wavelength, wherein the semiconductor chip is free of a growth substrate for the semiconductor layer sequence,
a plurality of contact elements arranged on the bottom, which are individually and mutually independently electrically activatable when operated as intended, wherein
the semiconductor layer sequence is subdivided into a plurality of emission regions arranged adjacent one another in the lateral direction, which emission regions are configured to emit radiation when in operation,
at least one of the contact elements is associated with each of the emission regions,
each emission region comprises a recess in the semiconductor layer sequence, which extends from the top in the direction of the active layer,
in plan view onto the top, the recess of each emission region is completely surrounded by a contiguous web of partitions, wherein the partitions are formed from the semiconductor layer sequence and wherein the partitions form boundaries between adjacent emission regions,
the lateral extent of the recesses of the emission regions decreases from the top in the direction of the active layer.
